(19) United States
(12) Patent Application Publication
(10) Pub. No.: US 2025/0149302 A1
(43) Pub. Date: May 8, 2025

(54) ANTI-PLASMA COATING

(71) Applicant: Taiwan Semiconductor Manufacturing Co., Ltd., Hsinchu (TW)

(72) Inventors: Chih-Kai Hu, Taoyuan County (TW); Ren-Guan Duan, Hsinchu City (TW); Chiun-Da Shiue, Hsinchu County (TW); Chin-Han Meng, Hsinchu City (TW)

(73) Assignee: Taiwan Semiconductor Manufacturing Co., Ltd., Hsinchu (TW)

(21) Appl. No.: 18/502,485

(22) Filed: Nov. 6, 2023

(51) Int. Cl. H01J 37/32; C23C 16/40; C23C 16/455; C23C 28/04

(52) U.S. Cl. CPC H01J 37/32495; C23C 16/403; C23C 16/405; C23C 16/45527; C23C 28/042; C23C 28/046; H01J 37/32467; H01J 2237/334

(57) ABSTRACT

An anti-plasma coating formed on a surface of a component in a plasma chamber includes an insulation layer on the surface and a plasma-resistant layer on the insulation layer. The plasma-resistant layer includes one or more stacks, where each stack includes a crystalline layer and an amorphous layer. The anti-plasma coating improves a lifetime of the component in the plasma chamber with high-energy plasma sources.

### BACKGROUND

In semiconductor manufacturing, some fabrication processes, such as an etching process, are performed by applying a high-energy plasma on semiconductor wafers in a chamber. The high-energy plasma can bombard and erode surfaces of components in the chamber, reducing the lifetime of the components and causing contamination on the semiconductor wafers and thus adversely affecting manufacturing efficiency, wafer yield, and integrated circuit (IC) performance.

### BRIEF DESCRIPTION OF THE DRAWINGS

Aspects of this disclosure are best understood from the following detailed description when read with the accompanying figures.

FIG. 1 illustrates a semiconductor manufacturing system, in accordance with some embodiments.

FIG. 2 illustrates a flow chart of a semiconductor manufacturing process, in accordance with some embodiments.

FIG. 3 illustrates a cross-sectional view of an anti-plasma coating on a component, in accordance with some embodiments.

FIG. 4 illustrates a cross-sectional view of an anti-plasma coating, in accordance with some embodiments.

FIG. 5 illustrates a flow chart of a method for forming an anti-plasma coating on a component, in accordance with some embodiments.

FIGS. 6-9 illustrate cross-sectional views of an anti-plasma coating at various stages of its fabrication process, in accordance with some embodiments.

FIGS. 10A and 10B illustrate anti-plasma coatings without and with an insulating bottom layer, respectively, in accordance with some embodiments.

FIG. 11 illustrates data about particle accumulated on test wafers in a plasma chamber, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows can include embodiments in which the first and second features are formed in direct contact, and can also include embodiments in which additional features can be formed between the first and second features, such that the first and second features can not be in direct contact. As used herein, the formation of a first feature on a second feature means the first feature is formed in direct contact with the second feature. In addition, the present disclosure can repeat reference numerals and/or letters in the various examples. This repetition does not in itself dictate a relationship between the various embodiments and/or configurations discussed.

Spatially relative terms, such as “beneath.” “below,” “lower.” “above.” “upper,” and the like can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

It is noted that references in the specification to “one embodiment.” “an embodiment,” “an example embodiment.” “exemplary,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., +1%, +2%, +3%, +4%, +5% of the value). These values are merely examples and are not intended to be limiting. The terms “about” and “substantially” can refer to a percentage of the values as interpreted by those skilled in relevant art(s) in light of the teachings herein.

Semiconductor manufacturing processes can include operations applying a plasma on wafers for various purposes, such as etching structures of the wafer with etchants activated by the plasma. The operations can be performed by providing etchants to a plasma chamber in which the wafers are disposed, generating a plasma in the plasma chamber, and exposing the wafers to the plasma-activated etchants.

When the plasma is generated in the plasma chamber, components in the plasma chamber can also be exposed to the plasma and are susceptible to damage by the plasma. For example, the plasma can bombard surfaces of the components, and/or the etchants activated by the plasma can be reactive to erode the surface of the components. In order to protect the components from being damaged by the plasma, an anti-plasma coating can be formed on the surfaces of the components, which involves spraying a layer of anti-plasma material on the surfaces of components, in accordance with some embodiments. The anti-plasma coating can be crystalline with a high porosity (e.g., about 5% to about 10%) and a high surface roughness (e.g., about 3 μm to about 4 μm). In order to achieve adequate protection, the layer of anti-plasma material can have a thickness of about 100 μm or greater.

The increasing demand of scaling down the dimensions of semiconductor devices gives rise to etching openings with higher aspect ratios (AR), corresponding to narrower widths and/or greater depths of the openings. One approach to meet such a requirement is to increase the energy of the plasma using high-energy plasma sources, which also poses a disadvantage to components in the plasma chamber, as the anti-plasma coating formed by the aforementioned spraying approach can no longer provide adequate protection against the high-energy plasma. The components with reduced lifetime due to the application of the high-energy plasma are subject to frequent replacement or repair, which can be time consuming, laborious, and costly.

Additionally, physical bombardments on the surface of the components by the high-energy plasma can generate particles away from the surface of the components (e.g., particles of the anti-plasma materials forming the anti-plasma coating). These particles can further accumulate on the wafers. The contamination of the particles on the wafers can affect subsequent manufacturing processes, result in malfunctioning of the semiconductor devices fabricated on the wafers, and jeopardize yield and throughput of the semiconductor manufacturing processes.

To address the challenges discussed above, the present disclosure provides embodiments of an anti-plasma coating that can adequately protect components in a plasma chamber applying a high-energy plasma. The anti-plasma coating can include a plurality of layers serving different purposes to protect the components and can be resistant to ion bombardment and radical erosion due to high-energy plasma, thus producing little or no particles accumulated on wafers. The present disclosure also provides a method of forming the anti-plasma coating.

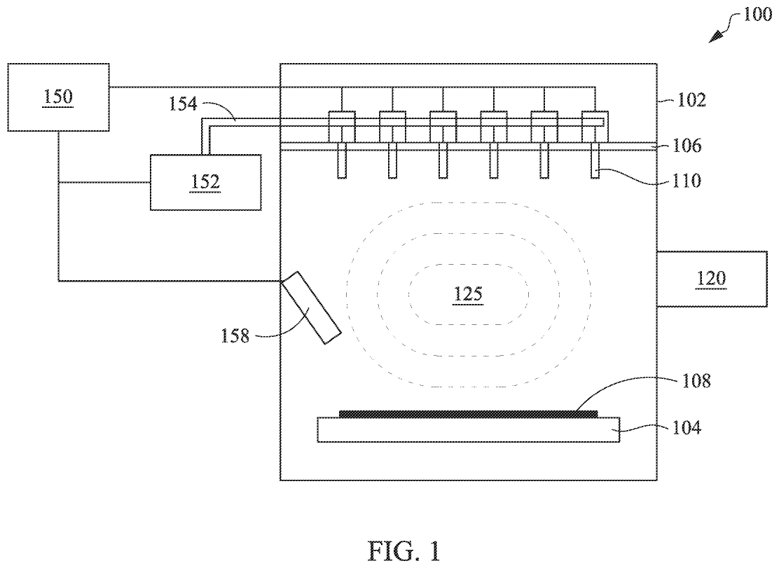

FIG. 1 illustrates a system 100 for semiconductor manufacturing, in accordance with some embodiments. System 100 can include a chamber 102, a wafer holder 104 in chamber 102 and configured to hold a wafer 108, a showerhead 106 in chamber 102 and disposed above wafer holder 104, and a plasma generator 120 configured to generate a plasma 125 in chamber 102. System 100 can further include one or more nozzles 110 mounted on showerhead 106 and coupled to a material supply device 152 via a material supply channel 154. System 100 can further include an analyzing device 158 and a control device 150 coupled to nozzles 110, material supply device 152, plasma generator 120, and analyzing device 158.

System 100 can include additional components for operation. By way of example and not limitation, such components can include transfer devices, robotic arms, view ports, shutters, pumps, valves, exhaust lines, heating elements, gas and chemical supply lines, controllers, valves, and external and internal electrical connections to other components of system 100 (e.g., temperature sensors, pressure sensors, chemical analyzers, temperature controllers, and pressure controllers). These additional components may not be depicted in FIG. 1 but are within the spirit and scope of this disclosure.

Chamber 102 can be a processing chamber providing a vacuum environment for conducting semiconductor manufacturing processes on wafer 108 in a vacuum environment (e g . . . a vacuum pressure below about 10⁻⁴ torr) to preserve, for example, a desired mean-free-path of reacting gases, plasma, and/or electrons in chamber 102 during the semiconductor manufacturing processes. In some embodiments, chamber 102 can be an etching chamber to perform etching operation on wafer 108 using etchants provided by nozzles 110 and activated by plasma 125. In some embodiments, chamber 102 can be a deposition chamber to perform thin-film deposition on wafer 108 by depositing materials on wafer 108. For example, chamber 102 can perform an epitaxial growth of a semiconductor layer using a plasma-enhanced chemical vapor deposition (PECVD) process, in which precursors provided by nozzles 110 can facilitate a semiconductor material to epitaxially grow on a semiconductor surface of wafer 108, while the etchants provided by nozzles 110 and activated by plasma 125 can remove the semiconductor material deposited on unwanted surfaces (e.g. a dielectric surface) of wafer 108.

Wafer holder 104 can be configured to hold wafer 108 during the semiconductor manufacturing processes. In some embodiments, wafer holder 104 can include a vacuum to secure wafer 108. In some embodiments, wafer holder 104 can include screws and pins to fix a position of wafer 108 on wafer holder 104. In some embodiments, wafer holder 104 can provide a controllable temperature controller for wafer 108. For example, wafer holder 104 can include a heater and/or a cooling channel through which coolant can flow. In some embodiments, wafer holder 104 can be driven by a motor and can rotate during the semiconductor manufacturing processes. In some embodiments, wafer holder 104 can applied a bias voltage to wafer 108 (e.g., to assist an etching operation by plasma 125). In some embodiments, wafer holder 104 can be configured to hold multiple wafers, similar to wafer 108, to be processed. In some embodiments, system 100 can include multiple wafer holders, similar to wafer holder 104, disposed in chamber 102.

Material supply device 152 can include one or more containers storing one or more materials in solid, liquid, and/or gas forms, and supply the materials to nozzles 110 through material supply channel 154. In some embodiments, material supply device 152 can include containers storing materials for forming structures in wafer 108. For example, material supply device 152 can include containers storing precursor gases and/or etchants for a PECVD process, a physical vapor deposition (PVD) process, an atomic layer deposition (ALD) process, and a molecular beam epitaxy (MBE) process. In some embodiments, material supply device 152 can include containers storing etchants for performing an etching operation on wafer 108.

Plasma generator 120 can be configured to generate plasma 125 based on the materials provided by nozzles 110. Plasma generator 120 can ionize the materials provided by nozzles 110 into charged ions to form plasma 125. Plasma generator 120 can vary an energy of plasma 125, according to a requirement of operations performed (e.g. an aspect ratio of an etching operation).

Analyzing device 158 can be disposed above a surface of wafer 108 and configured to analyze properties of wafer 108. In some embodiments, analyzing device 158 can implement an optical method to analyze the surface of wafer 108. For example, analyzing device 158 can include a camera to capture an image of the surface of wafer 108. In some embodiments, analyzing device 158 can count a quantity of particles accumulated on the surface of wafer 108 and evaluate a condition of wafer 108 contaminated by unwanted particles. In some embodiments, analyzing device 158 can be mounted on a robotic arm (not shown in FIG. 1) configured to drive analyzing device 158 across the surface of wafer 108 to count the quantity of particles accumulated on the surface of wafer 108.

Control device 150 can be configured to control the semiconductor manufacturing processes. In some embodiments, control device 150 can include a computer system. As shown in FIG. 1, control device 150 can be configured to communicate with nozzles 110, material supply device 152, plasma generator 120, and analyzing device 158. In some embodiments, the communication between control device 150 and the above elements can be via electrical cables and/or wireless means. In some embodiments, during a measurement operation, control device 150 can be configured to send commands to analyzing device 158 and control analyzing device 158 to scan the surface of wafer 108 and count a quantity of particles accumulated on the surface of wafer 108. In some embodiments, control device 150 can be configured to perform the manufacturing operation (e.g., a deposition operation or an etching operation), by i) controlling plasma generator 120 to generate plasma 125 with an adjustable energy and ii) controlling supply device 152 to provide the materials to nozzles 110 via material supply channel 154.

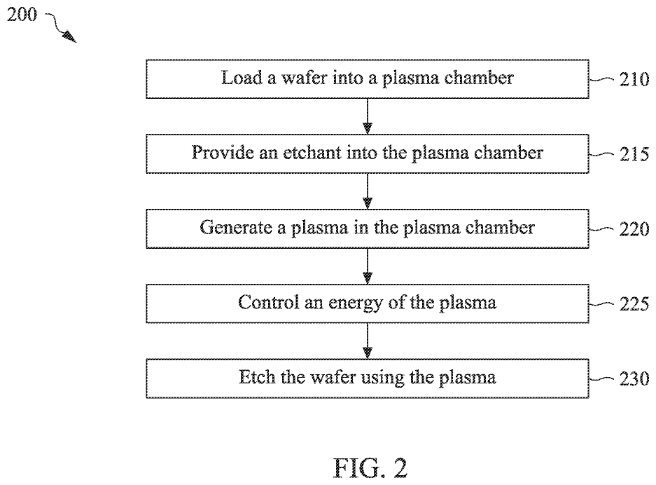

FIG. 2 illustrates a flow chart of an etching process 200 for semiconductor manufacturing, in accordance with some embodiments. The description of operations in etching process 200 can be with reference to system 100 in FIG. 1. It is to be appreciated that not all operations may be needed to perform the disclosure provided herein and that one or more additional operations may be performed. Further, some of the operations may be performed concurrently or in a different order than shown in FIG. 2.

In operation 210, a wafer is loaded into a plasma chamber. For example, as shown in FIG. 1, wafer 108 can be loaded onto wafer holder 104 in chamber 102. In operation 215, an etchant is provided into the plasma chamber. For example, as shown in FIG. 1, the etchant can be supplied by material supply device 152 via material supply channel 154 to nozzles 110 and provided into chamber 102.

In operation 220, a plasma is generated in the plasma chamber. For example, as shown in FIG. 1, plasma generator 120 can ionize the etchant to form plasma 125 in chamber 102.

In operation 225, an energy of the plasma is controlled. For example, as shown in FIG. 1, plasma generator 120 can increase an energy of plasma 125, and/or a voltage bias can be applied to wafer 108 by wafer holder 104, to determine an energy of the plasma that meets a fabrication requirement (e.g. a certain aspect ratio).

In operation 230, the wafer is etched using the plasma. For example, as shown in FIG. 1, a surface of wafer 108 can be exposed to and etched by plasma 125.

In etching process 200, components in the plasma chamber can be susceptible to damage when exposed to the plasma. For example, as shown in FIG. 1, components in chamber 102, such as showerhead 106, nozzles 110, analyzing device 158, wafer holder 104, and/or other inner surfaces of chamber 102 can be exposed to plasma 125 and damaged by plasma 125. In particular, as shown in FIG. 2, after operation 225, the energy of the plasma can be increased to etch features with high aspect ratios-thus, damaging components in the plasma chamber and/or producing particles that accumulate on the wafer.

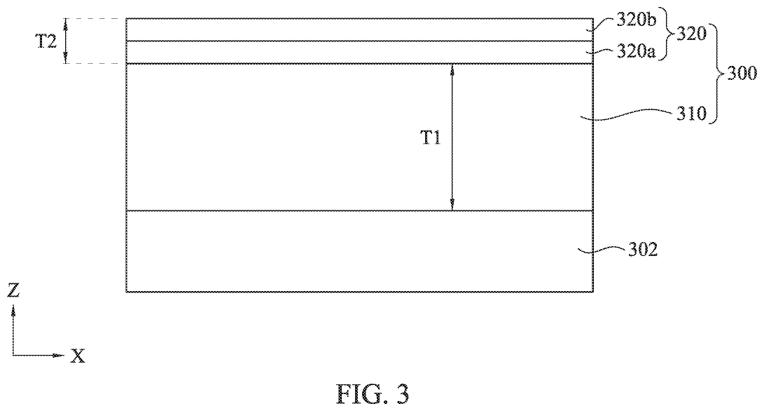

FIG. 3 illustrates a cross-sectional view of an anti-plasma coating 300 on a component to protect the component from being damaged by a plasma with a high energy, in accordance with some embodiments. As shown in FIG. 3, a surface of a component can include a substrate 302 coated with anti-plasma coating 300. In some embodiments, substrate 302 can include a metallic material. For example, substrate 302 can include aluminum, copper, titanium, zinc, chromium, and/or a combination thereof. Anti-plasma coating 300 can include an insulating layer 310 on substrate 302 and an anti-plasma layer 320 on insulating layer 310.

Insulating layer 310 can include an electrically insulating material, such as an oxide material or a nitride material. For example, insulating layer 310 can include silicon oxide (SiOₓ), hafnium oxide (HfOₓ), titanium oxide (TiOₓ), zirconium oxide (ZrOₓ), aluminum oxide (AlOₓ), yttrium oxide (YOₓ), silicon carbon oxide (SiOCₓ), silicon nitride (SiNₓ), and/or a combination thereof. In some embodiments, insulating layer 310 can be formed by depositing a layer of oxide material or a nitride material by a CVD process, a PVD process, a PECVD process, an electron beam ion assisted deposition (EB-IAD) process, or an ALD process. In some embodiments, insulating layer 310 can have a concentration of carbon less than about 5%. In some embodiments, insulating layer 310 can have an amorphous structure. In some embodiments, a thickness T1 of insulating layer 310 can be between about 1 μm and about 20 μm (e.g., about 1 μm, about 2 μm, about 5 μm, about 8 μm, about 10 μm, about 15 μm, and about 20 μm). In some embodiments, insulating layer 310 in this range of thicknesses can provide a total resistance of anti-plasma coating 300 to be greater than about 10⁹Ω. In some embodiments, a bulk resistivity of insulating layer 310 can be greater than about 10¹³ Ω·cm. In some embodiments, insulating layer 310 in this range of thicknesses can have a breakdown voltage greater than about 900 V. In some embodiments, if thickness T1 is less than about 1 μm, insulating layer 310 may not be thick enough to provide sufficient resistance to anti-plasma coating 300 and may not have a breakdown voltage high enough to protect anti-plasma coating 300 from electrical breakdown due to the high energy of the plasma. In some embodiments, if thickness T1 is greater than about 20 μm, an internal stress built during the deposition of insulating layer 310 can be too strong to introduce defects in insulating layer 310, which could be weak points with lower breakdown voltages and susceptible to the damage due to the plasma with high energy.

Anti-plasma layer 320 can include anti-plasma materials. For example, anti-plasma layer 320 can include YOₓ, SiOₓ, AlOₓ, yttrium aluminum garnet (YAG), magnesium oxide (MgOₓ), gadolinium oxide (GdOₓ), and/or a combination thereof. In some embodiments, anti-plasma layer 320 can be formed by depositing the anti-plasma materials by an ALD process, a PVD process, a PECVD process, an EB-IAD process, a CVD process, or a combination thereof.

Anti-plasma layer 320 can include a first sublayer 320a on insulating layer 310 and a second sublayer 320b on first sublayer 320a. In some embodiments, first sublayer 320a and second sublayer 320b can have different crystal structures. For example, first sublayer 320a can have an amorphous structure, and second sublayer 320b can have a crystalline structure. In some embodiments, first sublayer 320a can include YAG, and second sublayer 320b can include YOₓ. In some embodiments, second sublayer 320b can be harder than first sublayer 320a. In some embodiments, second sublayer 320b can provide a strong mechanical resistance to ion bombardment by the plasma with high energy. In some embodiments, first sublayer 320a can be a buffer layer that strongly bonds insulating layer 310 and second sublayer 320b, and can provide a softness and a flexibility to suppress a diffusion of the radicals, thus relaxing residual stresses caused by the diffusion of the radicals and providing a resistance to erosion due to radicals.

In some embodiments, a thickness T2 of anti-plasma layer 320 can be between about 500 nm and about 2 μm (e.g., about 500 nm, about 600 nm, about 800 nm, about 1 μm, about 1.5 μm, and about 2 μm). In some embodiments, anti-plasma layer 320 in this range of thicknesses can have a breakdown voltage greater than about 4 V. In some embodiments, if the thickness of anti-plasma layer 320 is less than about 500 nm, anti-plasma layer 320 may not be thick enough to provide sufficient resistance against the plasma with high energy and may not have a breakdown voltage high enough to protect anti-plasma coating 300 from electrical breakdown due to the high energy of the plasma. In some embodiments, if the thickness of anti-plasma layer 320 is greater than about 2 μm, an internal stress built in anti-plasma layer 320 during its deposition can be too strong to introduce internal defects in anti-plasma layer 320, which could be weak points with lower breakdown voltages and susceptible to damage by the plasma with high energy.

In some embodiments, anti-plasma layer 320 can have a surface roughness between about 0.5 μm and about 1 μm. In some embodiments, anti-plasma layer 320 can have a porosity below about 1%. For example, the porosity of anti-plasma layer 320 can be about 0%. In some embodiments, anti-plasma layer 320 can have a concentration of carbon less than about 5%. In some embodiments, anti-plasma layer 320 can have a concentration of hydrogen less than about 5%.

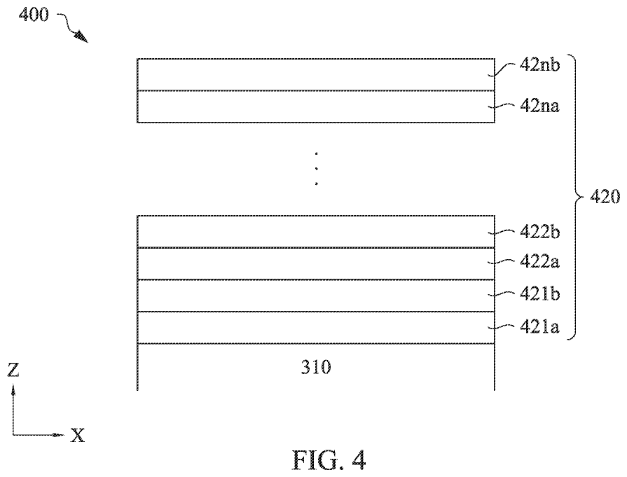

In some embodiments, anti-plasma coating 300 can further include more than one anti-plasma layers similar to anti-plasma layer 320 and stacking on insulating layer 310. FIG. 4 illustrates a cross-sectional view of an anti-plasma coating 400 including a stack of anti-plasma layers 420 on insulating layer 310, in accordance with some embodiments. The stack of anti-plasma layers 420 can include a number of anti-plasma layers, where each anti-plasma layer is the same as or similar to anti-plasma layer 320 as discussed with reference to FIG. 3, and where each anti-plasma layer includes an amorphous sublayer (421a, 422a, . . . , or 42na) similar to first sublayer 320a and a crystalline sublayer (421b, 422b, . . . or 42nb) similar to second sublayer 320b (here. ‘n’ represents a quantity of the anti-plasma layers, while ‘a’ and ‘b’ correspond to ‘amorphous sublayer’ and ‘crystalline sublayer’, respectively) In some embodiments, anti-plasma coating 400 can have a total thickness of greater than about 6 μm. In some embodiments, anti-plasma coating 400 can have a surface roughness between about 0.5 μm and about 1 μm. In some embodiments, anti-plasma coating 400 can have a total resistance greater than about 10⁹Ω. In some embodiments, anti-plasma coating 400 can have a porosity of about 0%.

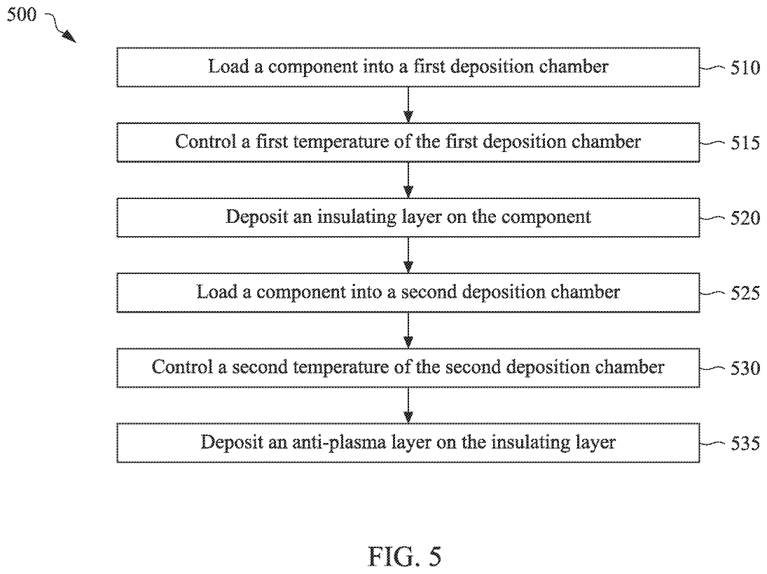

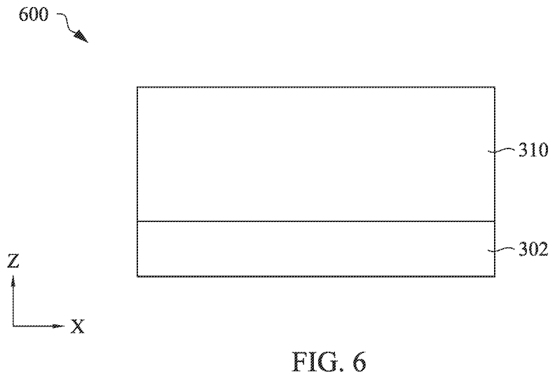

FIG. 5 illustrates a flow chart of a method 500 for forming an anti-plasma coating on a component, in accordance with some embodiments. In some embodiments, method 500 can be used to form anti-plasma coatings 300 and 400 as shown in FIGS. 3 and 4, respectively. For illustrative purposes, operations in method 500 will be described with reference to FIGS. 6-9. The discussion of elements in FIGS. 3 and 4 is applied to elements in FIGS. 6-9 with the same reference numbers, unless mentioned otherwise. The operations in method 500 can be performed in a different order, or some operations in method 500 may not be performed, depending on specific applications. Accordingly, it is understood that additional operations can be provided before, during, and after method 500, and that additional operations may only be briefly described herein.

In operation 510, the component to be coated with the anti-plasma coating is loaded into a first deposition chamber to form an insulating layer on a surface of the component. The component can be one of the components used in a plasma chamber. For example, the component can be one of showerhead 106, nozzles 110, analyzing device 158, and wafer holder 104, as shown in FIG. 1. As described with reference to FIG. 6, the surface of the component can have a substrate 302.

The first deposition chamber can be a deposition chamber suitable to deposit an insulating material, such as a CVD chamber, a PVD chamber, an ALD chamber, a PECVD chamber, and an EB-IAD chamber. For example, the first deposition chamber can be a CVD chamber, in which a layer of SiOₓ having a thickness of about 1 μm to about 20 μm can be deposited on the component using a C′VD process.

In operation 515, a first temperature of the first deposition chamber is controlled to provide a suitable environment to facilitate the deposition of the insulating material on the surface of the component. In some embodiments, the first temperature can be about 100° C. to about 400° C. For example, the first temperature can be about 100° C., about 200° C., about 250° C., about 300° C., and about 400° C.

In operation 520, the insulating material is deposited on the surface of the component to form an insulating layer. For example, as described with reference to FIG. 6, insulating layer 310 can be formed on substrate 302. Operation 520 can include providing a processing gas into the first chamber. For example, in a CVD process, silane (SiH₄) and oxygen (O₂) can be provided into the first chamber. By controlling the first temperature, silane and oxygen can react on substrate 302 to form SiO₂, which is deposited on substrate 302 and forms insulating layer 310 with an amorphous structure.

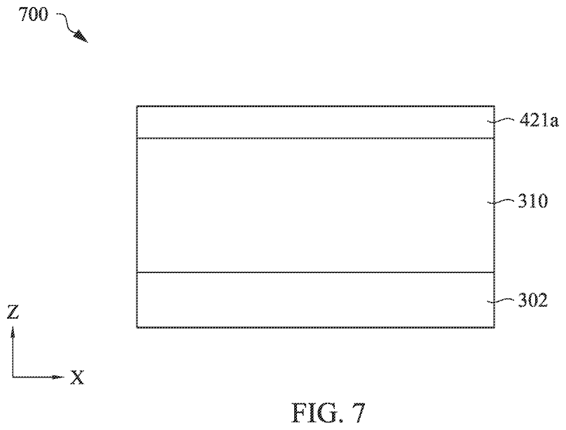

In operation 525, the component coated with the insulating layer is loaded into a second deposition chamber to form an anti-plasma layer on a surface of the component. As described with reference to FIGS. 7-9, an anti-plasma layer including a number of sublayers can be formed on insulating layer 310. In some embodiments, the second deposition chamber can be a deposition chamber suitable to deposit anti-plasma materials, such as a CVD chamber, a PVD chamber, an ALD chamber, a PECVD chamber, and an EB-IAD chamber. For example, the second deposition chamber can be an ALD chamber, in which atomic layers of YOₓ and atomic layers of YAG can be deposited on the insulating layer using an ALD process.

In some embodiments, the first and second deposition chambers can operate different deposition processes. In some embodiments, the first and second deposition chambers can operate a same deposition process. In some embodiments, the first and second deposition chambers can be the same deposition chamber, in which operation 525 (regarding loading the component from one deposition chamber to another) is not necessary.

In operation 530, a second temperature of the second deposition chamber is controlled to provide a suitable environment that facilitates the deposition of the anti-plasma materials on the insulating layer. In some embodiments, the second temperature can be about 100° C. to about 400° C. For example, the second temperature can be about 100° C., about 200° C., about 250° C.′, about 300° C., and about 400° C. In some embodiments, the second temperature can vary according to the requirement of depositing the anti-plasma materials in crystalline or amorphous forms.

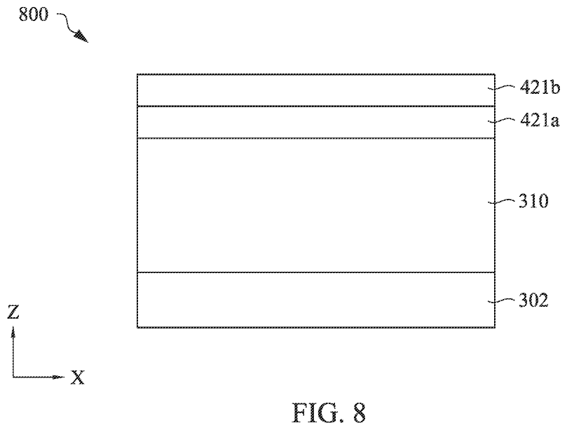

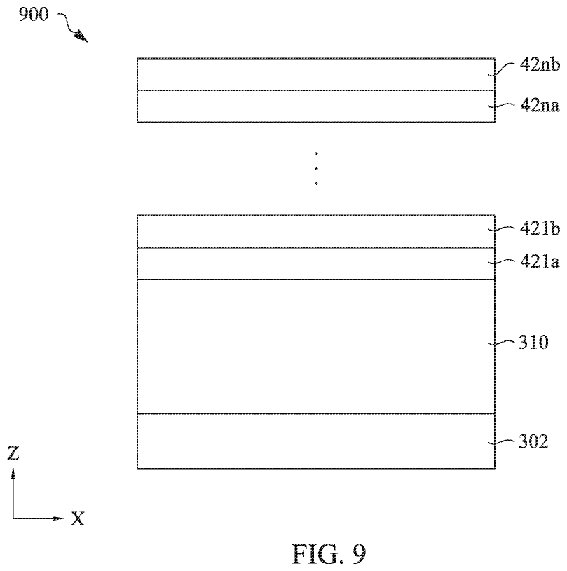

In operation 535, the anti-plasma layer is deposited on the surface of the component to form an insulating laver. The anti-plasma layer can be formed by depositing amorphous sublayers and crystalline sublayers in one or more deposition cycles. For example, as described with reference to FIGS. 7 and 8, in a first phase of a first deposition cycle, a first amorphous sublayer 421a can be formed on insulating layer 310 to form structure 700. In a second phase of the first deposition cycle, a first crystalline sublayer 421b can be formed on first amorphous sublayer 421a to form structure 800. As described with reference to FIG. 9, the deposition cycle can be repeated, such that a number of amorphous sublayers 421a to 42na and a number of crystalline layers 421b to 42nb can be deposited alternately to form structure 900.

Operation 535 can include providing processing gases into the second chamber. For example, in the first phase of each deposition cycle, a first yttrium precursor, an aluminum precursor, and a first oxygen precursor can be provided into the second chamber. In the second phase of each deposition cycle, a second yttrium precursor and a second oxygen precursor can be provided into the second chamber. In some embodiments, the first yttrium precursor can be the same as or different from the second yttrium precursor. In some embodiments, the first oxygen precursor can be the same as or different from the second oxygen precursor. The choice of the precursors is determined by the requirement of forming an amorphous structure or a crystalline structure of a sublayer (e.g., forming an amorphous sublayer in the first phase and forming a crystalline sublayer in the second phase). In some embodiments, the second temperature of the second deposition chamber can be maintained the same for both the first and the second phases of each deposition cycle. In some embodiments, the second temperature of the second deposition chamber can be varied for the first and the second phases of each deposition cycle. The choice of the second temperature is determined by the requirement of forming an amorphous structure or a crystalline structure of a sublayer.

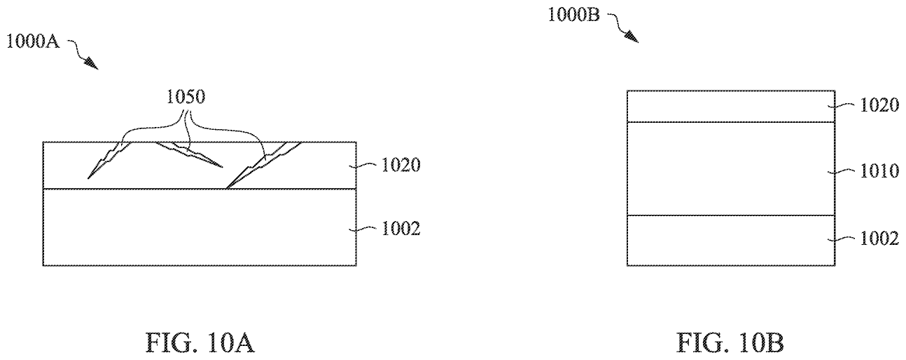

FIG. 10A illustrates a cross-sectional view of an anti-plasma coating 1000A without an insulating bottom layer, in accordance with some embodiments. FIG. 10B illustrates a cross-sectional view of an anti-plasma coatings 1000B with an insulating bottom layer, in accordance with some embodiments. Anti-plasma coatings 1000A and 1000B are disposed on a substrate 1002 and include anti-plasma layer 1020. Anti-plasma coating 1000B includes an insulating layer 1010 under anti-plasma layer 1020, while anti-plasma coating 1000A does not include an insulating layer under anti-plasma layer 1020. The previous discussions about substrate 302, insulating layer 310, and anti-plasma layers 320 and 420 in FIGS. 3 and 4 apply to substrate 1002, insulating layer 1010, and anti-plasma layer 1020, unless mentioned otherwise.

Anti-plasma coatings 1000A and 1000B can be tested by exposing them to a high-energy plasma. FIG. 10A shows that, without insulating layer 1010 in anti-plasma coating 1000A, cracks 1050 can be formed in anti-plasma layer 1020 after being tested for a period of time. On the other hand, FIG. 10B shows that, with insulating layer 1010 in anti-plasma coating 1000B, no cracks are formed in anti-plasma layer 1020 after being tested for the period of time. FIGS. 10A and 10B show that, by increasing a total resistance and a breakdown voltage of anti-plasma coating 1000B in comparison with anti-plasma coating 1000A, insulating layer 1010 under anti-plasma layer 1020 can better protect against the high-energy plasma.

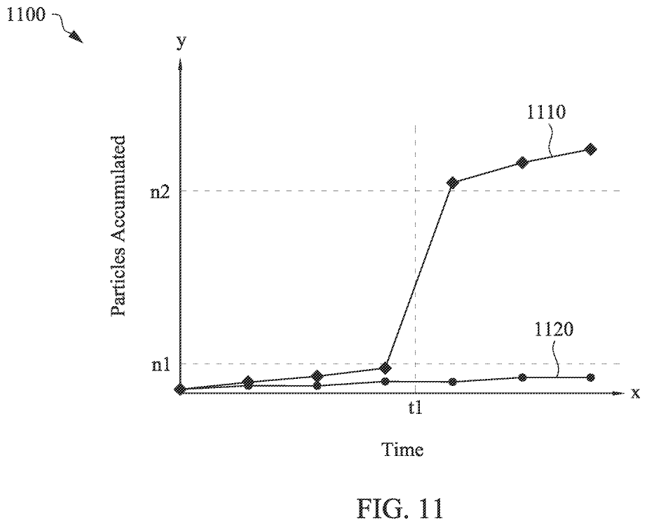

FIG. 11 illustrates data about particle accumulated on test wafers in a plasma chamber operating a high-energy plasma, in accordance with some embodiments. A first data 1110 refers to particles accumulated on a first test wafer as a function of a time of operation, with components in the plasma chamber coated by anti-plasma coating 1000A as shown in FIG. 10A. A second data 1120 refers to particle accumulated on a second test wafer as a function of the time of operation, with components in the plasma chamber coated by anti-plasma coating 1000B as shown in FIG. 10B. A horizontal axis (x-axis) is a coordinate of time of operating the high-energy plasma. When exposed to the high-energy plasma, anti-plasma coatings of components in the plasma chamber may produce particles due to the ion bombardment of the high-energy plasma. These particles may accumulate onto surfaces and the first and second test wafers and can be counted (for example, using analyzing device 158 as shown in FIG. 1). A vertical axis (y-axis) is a coordinate of a quantity of particles counted on first or second test wafers. Each data point on the first data 1110 and the second data 1120 represents the quantity of particles counted after a period of operating the high-energy plasma. For example, each data point can represent the quantity of particles counted after about every 10 hours of operating the high-energy plasma.

Referring to FIG. 11, first data 1110 shows a slow and gradual increase of particles accumulated on the first test wafer before a time t1. However, after the time t1, first data 1110 shows a sharp increase of particles accumulated on the first test wafer. This is because anti-plasma coating 1000A of the components can provide effective protection against the high-energy plasma only up to time t1, when cracks 1050 start forming in anti-plasma layer 1020, as shown in FIG. 10A. After time t1, anti-plasma coating 1000A can no longer provide effective protection against the high-energy plasma, and significant amount of particles are generated due to ion bombardment and accumulated onto the first test wafer. In some embodiments, before time t1, particles accumulated on the first test wafer is below a first level n1, and after time t1, particles accumulated on the first test wafer is beyond a second level n2. In some embodiments, a ratio between second level n2 and first level n1 can be about 10. In comparison, second data 1120 shows that anti-plasma coating 1000B of the components can provide effective protection against the high-energy plasma before and after time t1. In some embodiments, particles accumulated on the second test wafer is maintained to be below first level n1, indicating that insulating layer 1010 can prolong a lifetime of anti-plasma coating 1000B in comparison with anti-plasma coating 1000A.

The present disclosure provides examples of an anti-plasma coating for a component in a plasma chamber operating a high-energy plasma in semiconductor manufacturing processes. The anti-plasma coating includes an insulation layer on a surface of the component and an anti-plasma layer on the insulation laver. The anti-plasma layer includes one or more stacks, where each stack includes an amorphous layer and a crystalline layer on the amorphous laver. The insulating layer increases a total resistance and a breakdown voltage of the anti-plasma coating. The crystalline layer includes a first anti-plasma material and provides a mechanical resistance to an ion bombardment of the high-energy plasma. The amorphous layer includes a second anti-plasma material and provides a resistance to radical erosion by the high-energy plasma. The anti-plasma coating improves a lifetime of the component in the plasma chamber with high-energy plasma sources. The anti-plasma coating also reduces a contamination of wafers in the plasma chamber by suppressing a generation of particles due to the ion bombardment of the high-energy plasma, thus reducing an accumulation of the particles on the wafers.

The present disclosure also provides examples of a method for forming the anti-plasma coating. The method includes sequentially forming the insulating layer and the anti-plasma layer. The insulating layer can be formed by depositing an insulating material on the surface of the components using a CVD process, a PVD process, a PECVD process, an ALD process, or an EB-IAD process. The anti-plasma layer can be formed by forming the amorphous layer and the crystalline layer using a CVD process, a PVD process, a PECVD process, an ALD process, an EB-IAD process, or a combination thereof.

In some embodiments, a coating can include an insulating layer on a substrate and an anti-plasma layer on the insulating layer. The anti-plasma layer can include an amorphous layer and a crystalline layer on the amorphous layer. The amorphous layer can include a first insulating material. The crystalline layer can include a second insulating material different from the first insulating material.

In some embodiments, a method can include depositing an oxide material on a component surface and forming an anti-plasma layer on the oxide material. Formation of the anti-plasma layer can include forming an amorphous layer and a crystalline layer. The amorphous layer can include a first plasma-resistant material. The crystalline layer can include a second plasma-resistant material different from the first plasma-resistant material.

In some embodiments, a component can include a surface having a metallic substrate, an insulating layer on the metallic substrate, and a stack of layers on the insulating layer. Each layer in the stack of layers can be plasma resistant. The stack of layers can include a first layer with a first material structure and a second layer with a second material structure different from the first material structure.

The foregoing disclosure outlines features of several embodiments so that those skilled in the art can better understand the aspects of the present disclosure. Those skilled in the art should appreciate that they can readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they can make various changes, substitutions, and alterations herein without departing from the spirit and scope of the present disclosure.

What is claimed is:

1. A coating, comprising:
an insulating layer on a substrate; and
an anti-plasma layer on the insulating layer, wherein the anti-plasma layer comprises:
an amorphous layer comprising a first insulating material; and
a crystalline layer, on the amorphous layer, comprising a second insulating material different from the first insulating material.

2. The coating of claim 1, wherein the first insulating material comprises yttrium aluminum oxide and the second insulating material comprises yttrium oxide.

3. The coating of claim 1, wherein the anti-plasma layer further comprises an oxide of silicon, magnesium, gadolinium, aluminum, yttrium, or a combination thereof.

4. The coating of claim 1, wherein a thickness of the anti-plasma layer is between about 500 nm and about 5 μm.

5. The coating of claim 1, wherein a thickness of the insulating layer is between about 1 μm and about 20 μm.

6. The coating of claim 1, wherein a total resistance of the insulating layer and the anti-plasma layer is greater than about 10⁹Ω.

7. The coating of claim 1, wherein the insulating layer comprises an oxide of silicon, carbon, aluminum, yttrium, titanium, hafnium, or a combination thereof.

8. A method, comprising:
depositing an oxide material on a component surface; and
forming an anti-plasma layer on the oxide material, comprising:
forming an amorphous layer comprising a first plasma-resistant material; and
forming, on the amorphous layer, a crystalline layer comprising a second plasma-resistant material different from the first plasma-resistant material.

9. The method of claim 8, wherein depositing the oxide material comprises forming a layer of the oxide material using a chemical vapor deposition process or a physical vapor deposition process.

10. The method of claim 8, wherein depositing the oxide material comprises forming a layer of the oxide material at a temperature between about 100° C. and about 400° C.

11. The method of claim 8, wherein forming the anti-plasma layer further comprises depositing the first and second plasma-resistant materials using an atomic layer deposition process.

12. The method of claim 8, wherein forming the amorphous layer comprises depositing yttrium aluminum oxide at a temperature between about 100° C. and about 400° C.

13. The method of claim 8, wherein forming the crystalline layer comprises depositing yttrium oxide at a temperature between about 100° C. and about 400° C.

14. A component, comprising:
a surface comprising a metallic substrate;
an insulating layer on the metallic substrate; and
a stack of layers on the insulating layer, wherein each layer in the stack of layers is plasma resistant, and wherein the stack of layers comprises:
a first layer with a first material structure; and
a second layer with a second material structure different from the first material structure.

15. The component of claim 14, wherein a concentration of carbon in the insulating layer is less than about 5%.

16. The component of claim 14, wherein a concentration of carbon and a concentration of hydrogen in the stack of layers are less than about 5%.

17. The component of claim 14, wherein a breakdown voltage of the stack of layers is greater than about 4 V.

18. The component of claim 14, wherein a breakdown voltage of the insulating layer is greater than about 900 V.

19. The component of claim 14, wherein:
a surface roughness of the stack of layers is less than about 1 μm; and
a porosity of the stack of layers is less than about 1%.

20. The component of claim 14, wherein:
the first material structure is crystalline and resistant to ion bombardment; and
the second material structure is amorphous and resistant to radical erosion.
